(19) United States
(12) Patent Application Publication
(10) Pub. No.: US 2026/0188394 A1
(43) Pub. Date: Jul. 2, 2026

(54) POWER SUPPLY FOR LOW POWER MODES IN MEMORY

(71) Applicant: Micron Technology, Inc., Boise, ID (US)

(72) Inventors: Liang Yu, Boise, ID (US); Jonathan S. Parry, Boise, ID (US); Chulbum Kim, San Jose, CA (US)

(21) Appl. No.: 19/418,381

(22) Filed: Dec. 12, 2025

Related U.S. Application Data
(60) Provisional application No. 63/739,328, filed on Dec. 27, 2024.

(51) Int. Cl. G11C 16/30; G11C 5/14; G11C 16/26

(52) U.S. Cl. CPC G11C 16/30; G11C 5/141; G11C 16/26

(57) ABSTRACT

Methods, systems, and devices for power supply for low power modes in memory are described. A memory system may include one or more memory devices, a controller, a first voltage source associated with a first supply rail, and a second voltage source associated with a second supply rail. During an active mode, a memory device may be coupled with the first voltage source and the first supply rail. In some examples, the controller may send a command to the memory device to enter a low power mode, or to couple with the second voltage source, after which the memory device may couple one or more components with the second supply rail and the second voltage source. Additionally, or alternatively, the one or more components may be coupled with the second voltage source in response to a voltage of the first voltage source failing to satisfy a threshold.

### CROSS REFERENCE

The present Application for Patent claims priority to U.S. patent application Ser. No. 63/739,328 by Yu et al., entitled “POWER SUPPLY FOR LOW POWER MODES IN MEMORY,” filed Dec. 27, 2024, which is assigned to the assignee hereof, and which is expressly incorporated by reference in its entirety herein.

### TECHNICAL FIELD

The following relates to one or more systems for memory, including power supply for low power modes in memory.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports power supply for low power modes in memory in accordance with examples as disclosed herein.

FIGS. 2A and 2B show examples of circuit diagrams that support power supply for low power modes in memory in accordance with examples as disclosed herein.

FIGS. 3A and 3B show examples of circuit diagrams that support power supply for low power modes in memory in accordance with examples as disclosed herein.

FIGS. 4A and 4B show examples of circuit diagrams that support power supply for low power modes in memory in accordance with examples as disclosed herein.

FIGS. 5A and 5B show examples of circuit diagrams that support power supply for low power modes in memory in accordance with examples as disclosed herein.

FIG. 6 shows a block diagram of a memory system that supports power supply for low power modes in memory in accordance with examples as disclosed herein.

FIGS. 7 and 8 show flowcharts illustrating a method or methods that support power supply for low power modes in memory in accordance with examples as disclosed herein.

### DETAILED DESCRIPTION

Memory devices (e.g., NAND devices) may be coupled with different power rails of a memory system. For example, a memory system may include a first supply rail (e.g., a power supply rail) coupled with a first voltage source and a second supply rail coupled with a second voltage source. In some cases, the first voltage source may be associated with a relatively high voltage level (e.g., Vcc, 2.5 V) used for access operations, register use, or other relatively high power operations, while the second voltage source may be associated with a lower, or relatively low, voltage level (e.g., Vccq, 1.2 V) used for input/output (I/O) operations involving control signaling exchanged between a memory device and a controller or a datapath, among other relatively low power operations. Memory systems and memory devices may in some cases support a low power mode (e.g., a sleep mode, a deep sleep mode, a hibernate mode) during which the first supply rail may be powered down, or one or more memory devices may lose power provided by the first voltage source during operation. Loss of the first voltage source may in some cases result in losing temporary data held in volatile storage of a memory device (e.g., in static random access memory (SRAM)), and thus, on boot-up after power is restored or a low power mode is exited, the memory device may first perform additional initialization procedures, including reloading the lost data (e.g., reading a read-only memory (ROM) and storing to volatile memory). However, additional initialization procedures may increase a boot-up time, adding latency to operations and decreasing performance.

Techniques described herein may support enabling power supplies for low power modes in memory. In some examples, switches and circuitry may enable memory devices to access the second voltage source during low power modes or after power loss. For example, a controller of a memory system (e.g., an application specific integrated circuit (ASIC)) may send a command to a memory device to enter a low power mode, or to couple with the second voltage source during the low power mode, after which the memory device may couple components within the memory device with the second supply rail. In another example, the controller, or the memory device, may monitor a voltage level of the first voltage source, and upon power loss, may automatically switch components within the memory device to be coupled with the second supply rail. Different circuit designs may be contemplated, including switching circuitry located on memory devices (e.g., located on a same substrate or device, coupled within a relative proximity), on the controller, or elsewhere in a memory system or package. Further examples may include voltage monitoring circuitry (e.g., logic circuitry for monitoring a voltage level of voltage sources) or added conductive pads, among other components.

In addition to applicability in memory systems as described herein, techniques enabling power supply for low power modes in memory may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling memory device access to another supply rail, such as a supply rail for Vccq, while in a sleep mode or other low power mode, enabling retention of data in the event of a power loss or low power mode transition. Retention of such data may decrease processing or latency times incurred after power on, as reloading such data may be skipped, among other benefits.

Features of the disclosure are illustrated and described in the context of systems, devices, and circuits. Features of the disclosure are further illustrated and described in the context of systems, block diagrams, and flowcharts.

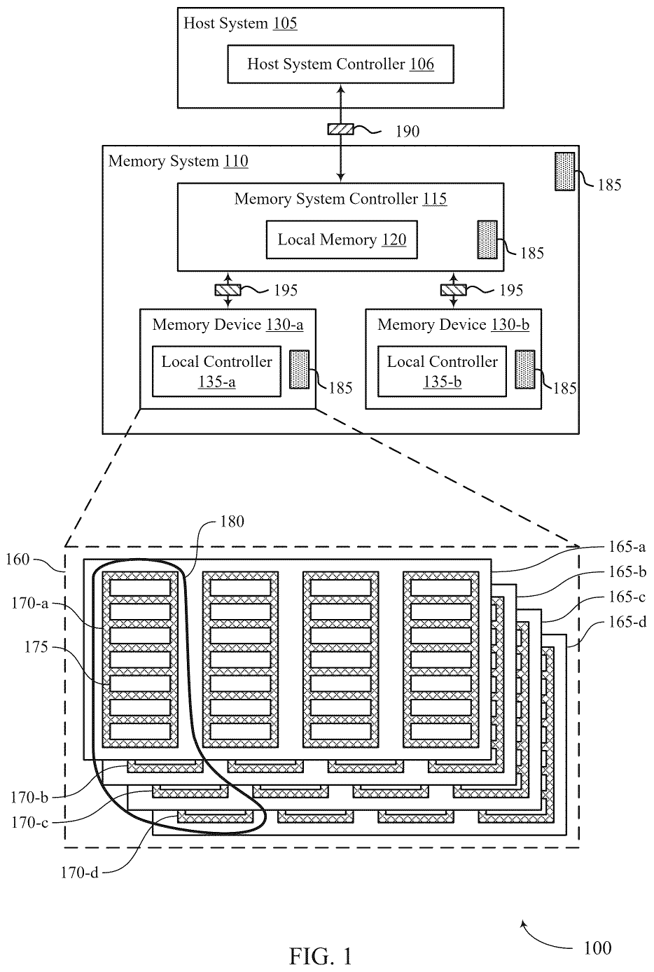

FIG. 1 shows an example of a system 100 that supports power supply for low power modes in memory in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0 ” of plane 165-a, block 170-b may be “block 0 ” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

Memory devices 130 (e.g., NAND devices) may be coupled with different power rails of the memory system 110. For example, the memory system 110 may include a first supply rail that may be used for power intensive operations, including access operations and register use, among other operations. The first supply rail may be coupled with a first voltage source associated with a relatively high voltage level (e.g., Vcc, 2.5 V). Additionally, or alternatively, the memory system 110 may include a second supply rail that may be used for operations involving less power usage, including I/O operations involving control signaling exchanged between one or more memory devices 130 and a controller (e.g., with the memory system controller 115) or a datapath. The second supply rail may be coupled with a second voltage source associated with a relatively low voltage level (e.g., Vccq, 1.2 V). Memory devices 130 may in some cases support a low power mode (e.g., a sleep mode) during which the first voltage source may be powered down, or one or more memory devices 130 may lose power provided by the first voltage source during operation. Loss of the first voltage source may in some cases result in losing temporary data held in volatile storage of a memory device 130 (e.g., in SRAM), and thus, on boot-up after power is restored or a low power mode is exited, the memory device 130 may first perform additional initialization procedures, including reloading the lost data, increasing a boot-up time and adding latency to operations while decreasing performance.

As described herein, the system 100 may support enabling power supplies for low power modes in memory. For example, the memory system 110 may include circuitry 185 (e.g., switches, logic circuitry, contact pads, wiring, conductors, and the like) that may enable memory devices 130 to access the second voltage source during low power modes or after power loss. In some cases, circuitry 185 may be included in memory devices 130, in the memory system controller 115 (e.g., at an ASIC), or both, or may be distributed among the memory system controller 115 and memory devices 130 (e.g., with switches at a memory device and logic circuitry at an ASIC, or vice versa). Additionally, or alternatively, circuitry 185 may be located elsewhere in the memory system 110 or in a package comprising the memory system 110. In some cases, the memory system controller 115 may receive a command 190 to enter a low power mode and/or may send one or more commands 195 to the memory devices 130 to enter the low power mode (or to couple with the second voltage source during the low power mode). Additionally, or alternatively, the memory system controller 115, or the memory devices 130, may monitor the first voltage source using respective circuitry 185 (e.g., voltage monitoring circuitry), and upon power loss, may automatically switch coupling of supply rails (e.g., via switches of the circuitry 185).

The system 100 may include any quantity of non-transitory computer readable media that support power supply for low power modes in memory. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

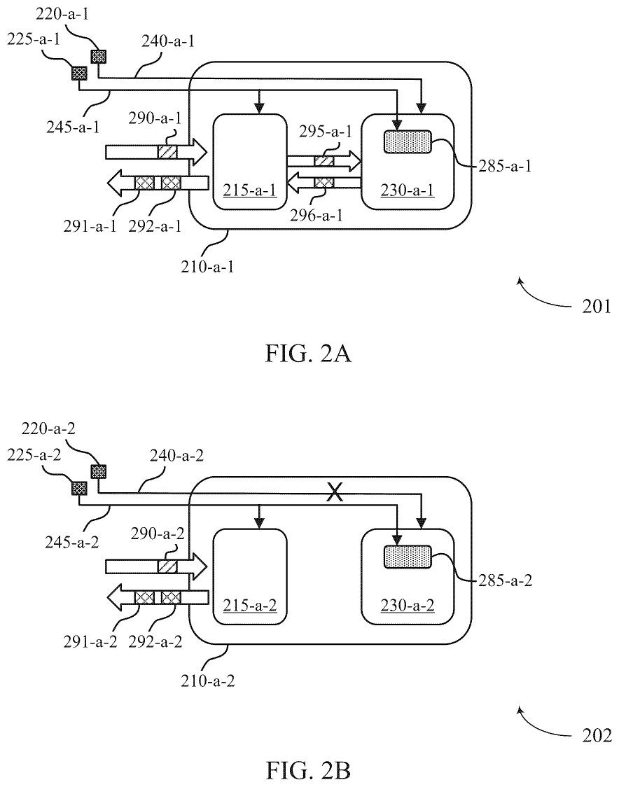

FIGS. 2A and 2B show examples of circuit diagrams 201 and 202 that support power supply for low power modes in memory in accordance with examples as disclosed herein. One or more aspects of the circuit diagrams 201 and 202 may implement or may be implemented by one or more aspects of the system 100. For example, the circuit diagrams 201 and 202 may illustrate circuitry of memory systems 210-a-1 and 210-a-2 including a controller 215-a-1 and a controller 215-a-2, respectively, and one or more memory devices 230, which may be examples of the memory system 110, memory system controller 115, and memory devices 130 described with respect to FIG. 1. In some cases, the circuit diagrams 201 and 202 may support power supply for low power modes of memory devices as described herein.

In the example of FIG. 2A, the memory system 210-a-1 may include one or more memory devices 230, including a memory device 230-a-1 with one or more memory arrays, as well as a controller 215-a-1 coupled with the one or more memory devices 230. The memory system 210-a-1 may also be coupled with one or more voltage sources coupled with the one or more memory devices 130, including a voltage source 220-a-1 and a voltage source 225-a-1. In some examples, the voltage sources 220-a-1 and 225-a-1 may couple with the one or more memory devices 230 via a supply rail 240-a-1 and a supply rail 245-a-1, respectively.

In some examples, the voltage source 220-a-1 may be configured to power one or more components of the one or more memory devices 230 at a first voltage level (e.g., Vcc, 2.5 V) used for various operations involved with a relatively high power consumption. In some cases, the one or more components may be supplied at a voltage level lower than the first voltage level. In some cases, such components may be referred to as low voltage components (e.g., static supply buffer (SPB), registers, SRAM), where low voltage components may correspond to components or other elements of one or more memory devices 230 that are supplied by a third voltage level that is lower than the first voltage level. In some cases, the third voltage level may be generated from the first voltage level. For example, a regulator (e.g., low-dropout (LDO) regulator) may be used to reduce the first voltage level (e.g., 2.5 V, which may be used to power an array for access operations) supplied by the voltage supply 220-a-1 to the third voltage level (e.g., 1.8 V). In some cases, the one or more memory devices 230 may include circuitry 285, which may include low voltage logic circuitry for controlling low voltage components and/or the low voltage components. Additionally, or alternatively, the voltage source 225-a-1 may be configured to power other components at a second voltage level (e.g., Vccq, 1.2 V). In some examples, the second voltage level may be lower than the first voltage level and the third voltage level, and may be used for operations involved with a relatively low power (e.g., control signaling with the controller 215-a-1). In some cases, the memory system 210-a-1 may include the voltage sources 220-a-1 and 225-a-1, or the voltage sources 220-a-1 and 225-a-1 may be external to the memory system 210-a-1.

In some examples, the power rail 240-a-1 may be powered down during one or more low power modes. For example, a mobile host system (e.g., a host system 105) may control power to the supply rail 240-a-1 and may power down the supply rail 240-a-1 in a sleep mode. The supply rail 240-a-1 may, in some cases, be partially powered down, or fully powered down, and one or more memory devices may be reset. For example, if the supply rail 240-a-1 is decoupled from the voltage source 220-a-1, the memory device 230-a-1 may be without power during the sleep mode, and may be reset upon power on. In some cases, loss of power at the memory device 230-a-1 may result in a loss of data temporarily stored in a local memory, such as volatile memory that may lose power. After power on and recoupling with the voltage source 220-a-1 for entering an active mode, the memory system 230-a-1 may read data stored in a ROM of the memory system 210-a-1 and store the data in the local memory of the memory device 230, and may perform one or more other power-on and initialization procedures. Such procedures may increase a boot-up time of the memory device 230-a-1 before being ready for operation, adding latency and reducing a performance of an overall system.

In some examples, coupling of one or more components of the memory device 230-a-1 may be switched to a different supply rail during one or more low power modes. For example, while the memory system 210-a-1 may be configured to couple the one or more components of the one or more memory devices 230 with the voltage source 220-a-1 during an active mode, the memory system 210-a-1 may also be configured to couple the one or more components of the one or more memory devices 230, such as low voltage components, with the voltage source 225-a-1 (e.g., Vccq) during a low power mode (e.g., a sleep mode, a start-stop unit (SSU) sleep mode, a deep sleep mode, a hibernate mode). The memory system 210-a-1 may further include additional circuitry to support such techniques, including switches, logic circuitry, conductive pads, among other components, to enable switching to the voltage source 225-a-1. In some cases, the additional circuitry may be on the one or more memory devices 230, and/or on the controller 215-a-1, for coupling the one or more components of the one or more memory devices 230 with the supply rail 245-a-1. In some cases, circuitry 285-a-1 (e.g., low voltage logic circuitry) may include the additional circuitry.

In some examples, FIG. 2A may illustrate switching to the supply rail 245-a-1 during a sleep mode in response to one or more commands. For example, during an active mode, the controller 215-a-1 (e.g., an ASIC, an mNAND controller) may monitor a channel coupled with a host system (e.g., a host system 105) for one or more commands, and may receive a command 290-a-1 (e.g., a sleep mode request) indicating to enter a low power mode. In response to the command 290-a-1, the controller 215-a-1 may determine to enter the one or more memory devices 230 into a low power mode, and may transmit one or more commands 295 to the one or more memory devices 230 (e.g., NAND memory devices) indicating to enter the low power mode (e.g., to switch low voltage components from Vcc to Vccq for sleep), including a command 295-a-1 transmitted to the memory device 230-a-1. Additionally, or alternatively, the controller 215-a-1 may transmit a confirmation 291-a-1 (e.g., a sleep confirmation sent after handshake timing) to the host system. In some cases, the controller 215-a-1 may support power gating (e.g., decoupling power supply for one or more components of the controller 215-a-1, the memory system 210-a-1, or both) and may remain on during the low power mode.

In response to the commands 295, the memory device 230-a-1 may determine to enter a low power mode. In some cases, the commands may be part of one or more operations to couple the one or more memory devices 230 with the voltage source 225-a-1, where the memory device 230-a-1 may perform the coupling. In some examples, the memory device 230-a-1 may transmit an indication 296-a-1 to the controller 215-a-1 that the one or more components are coupled with the voltage source 225-a-1. Additionally, or alternatively, the controller 215-a-1 may transmit a confirmation 292-a-1 that the one or more memory devices 230 successfully entered a low power mode (e.g., a hibernate confirm). In some cases, the supply rail 240-a-1 may be powered down during the sleep mode, or may be left powered on (e.g., as controlled by the mobile host). In some examples, verification of data may be performed after re-entering an active mode at a later time. For example, the controller 215-a-1 may determine data reloading is skipped due to a shorter boot-time, or in response to one or more error correction operations performed on data returning an error quantity less than a threshold. In some cases, an option may be included in the memory system 210-a-1, or within one or more memory devices, to enable or disable switching voltage sources (e.g., a voltage supply backup feature stored in NAND set feature register or SRAM).

FIG. 2B may illustrate switching to a backup supply rail 245 in response to power loss auto detection. For example, the memory system 210-a-1 may include supply rails 240-a-1 and 245-a-2 coupled with voltage supplies 220-a-1 (e.g., Vcc) and 225-a-1 (Vccq), respectively, and may receive a similar command 290-a-2 to enter a low power mode and transmit a confirmation 291-a-1 (e.g., a sleep confirm). In some cases, one or more memory devices 230 of the memory system 210-a-2, including a memory device 230-a-2, may be in a standby mode or Low Power Mode Standby (LPMS) during sleep request. In some cases, a standby mode may be associated with a first regulator voltage (e.g., a 2.2V internal Vcc regulator voltage output) while an LPMS may be associated with a second regulator voltage (e.g., 1.8V or lower internal Vcc regulator voltage output). LPMS may in some cases be associated with relatively less leakage compared to one or more other standby modes. In some examples, the memory device 230-a-2, the controller 215-a-2, or both, may monitor a voltage of the voltage source 220-a-2 using voltage monitoring circuitry located on the memory deice 230-a-2 or the controller 215-a-2 (e.g., respective circuitry on each memory device 230, shared between memory devices 230, or external to the one or more memory devices 230). In some cases, voltage monitoring circuitry may be powered by the supply rail 245-a-1 (e.g., voltage supply rail), may include pumping circuitry to generate a reference voltage, and may monitor to determine if the voltage of the supply rail 240-a-2 falls below the reference voltage to determine to switch power rails.

In some cases, if it is determined (e.g., detected) that the voltage fails to satisfy a threshold voltage (e.g., falls below the reference voltage, is powered down), the voltage monitoring circuitry may output a signal indicating to switch to the supply rail 245-b-1. Thus, the memory device 230-a-2 may determine, in response to a signal output by the voltage monitoring circuitry or a signal from the controller 215-a-2, to enter the low power mode, and the one or more components may be coupled with the voltage source 225-a-2 and the supply rail 245-a-2 using circuitry 285-a-2. The controller 215-b-2 may also transmit a confirmation 292-a-2 after the one or more memory devices 230 enter the low power mode and/or couple the one or more components with the voltage source 225-a-2. The controller 215-a-2 may also support power gating and may remain active during the sleep mode.

In some examples, coupling one or more components of one or more memory devices 230 with a lower voltage level voltage supply during a low power mode may enable data retention and thus reduce boot-up time. For example, while low voltage components may operate at a reduced functionality if supplied by the second voltage level as compared to operation at full functionality if supplied by the first voltage level or the third voltage level, the reduced functionality may be sufficient for retention of information or limited processing associated with the low power mode. For example, the second voltage level may be sufficient to retain data within a local memory (e.g., SRAM) that may typically use higher voltages (e.g., the first voltage level, the third voltage level) for access operations.

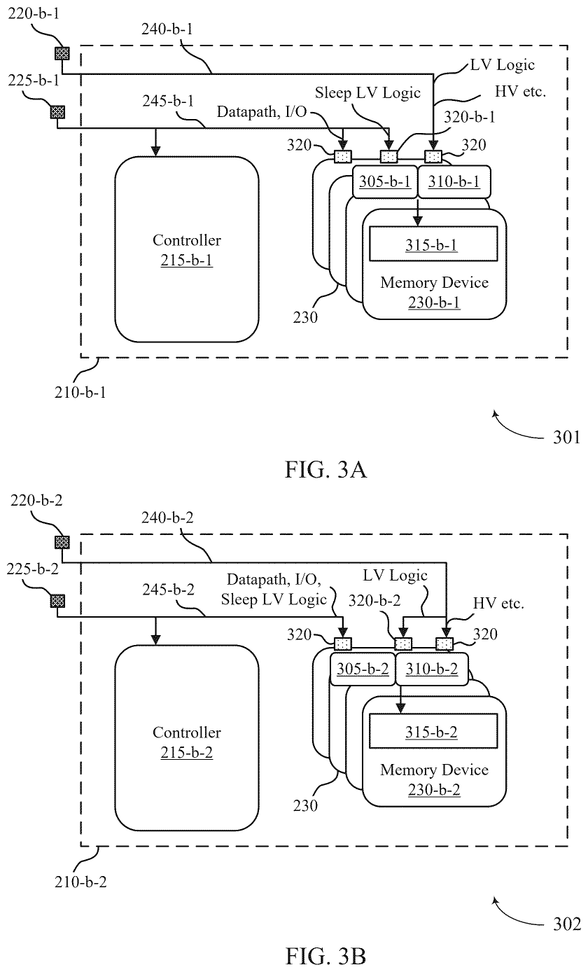

FIGS. 3A and 3B show examples of circuit diagrams 301 and 302 that support power supply for low power modes in memory in accordance with examples as disclosed herein. One or more aspects of the circuit diagrams 301 and 302 may implement or may be implemented by one or more aspects of the system 100 and the circuit diagrams 201 and 202. For example, the circuit diagrams 301 and 302 may illustrate circuitry of memory systems 210-b-1 and 210-b-2, including a controller 215-b-1 and a controller 215-b-2, respectively, and including one or more memory devices 230. The memory system 210-b-1 may also include voltage sources 220-b-1 and 225-b-1 with supply rails 240-b-1 and 240-b-1, respectively, and the memory system 210-b-2 may include voltage sources 220-b-2 and 225-b-2 with supply rails 240-b-2 and 245-b-2, respectively. In some cases, the circuit diagrams 301 and 302 may illustrate memory device control of voltage source switching for low power modes.

For example, in the example of FIG. 3A, the supply rail 240-b-1 may be coupled with the one or more memory devices 230, including a memory device 230-b-1, and may power one or more relatively high power operations during an active mode. The supply rail 245-b-1 may be coupled with the controller 215-b-1 and with the one or more memory devices 230, and may supply power for a datapath or for I/O and control signaling (e.g., between the controller 215-b-1 and the memory devices 230).

In some examples, the memory system 210-b-1 may include one or more switching components located on the one or more memory devices 230, for example, including a switching component 305-b-1 and a switching component 310-b-1 (or additional other switching components). In some cases, the switching components 305-b-1 and 310-b-1 (e.g., switches, logic circuitry configured to switch between power sources) may represent respective components for the memory device 230-b-1 (where each memory device 230 may include a respective pair of switching components), or one or both may be shared among the memory devices. The one or more memory devices 230 may include circuitry 315 as well. For example, the memory device 230-b-1 may include circuitry 315-b-1, which may include any one of low voltage logic circuitry (e.g., logic circuitry associated with operation of low voltage components) as well as low voltage components, including a static page buffer (SPB), a local memory (e.g., SRAM), or registers. In some examples, the voltage source 220-b-1 may output a voltage level for running one or more components during an active mode. For example, the voltage source 220-b-1 may output a first voltage level, such as Vcc (e.g., 2.5V) used for powering high voltage, or HV, components, such as components for sense, bias, program, erase, and other access operations for bit lines or word lines. Additionally, or alternatively, the voltage source 225-b-1 may output a lower, second voltage level, such as Vccq (e.g., 1.2V). Further, a regulator (e.g., LDO) at one or more components of the memory system 210-b-1 may output a third voltage level (e.g., 1.8V) for running one or more low voltage components (e.g., LV components) and/or associated low voltage logic (e.g., LV logic), where the regulator may be supplied by the first voltage source 220-b-1. In some cases, the third voltage level may be the same or different than a voltage used for running relatively high speed operations (e.g., Vcclo).

In some examples, during an active mode, the switching component 310-b-1 (e.g., one or more Vcc switches including an LDO) may be configured to couple the supply rail 240-b-1 associated with the voltage source 220-b-1 (e.g., Vcc) with low voltage components and low voltage logic circuitry. For example, the switching component 310-b-1 may be configured to couple an LDO with Vcc, where the LDO may be coupled with the components to provide Vcclo or another lowered voltage level. Additionally, or alternatively, the switching component 305-b-1 (e.g., a Vccq switch) may be configured to couple the supply rail 245-b-1 associated with the voltage source 225-b-1 (e.g., Vccq) with one or more power supply nodes associated with the one or more memory devices 230 (e.g., a single power supply node, a shared power supply node) during a low power mode by activating the switching component. For example, the coupling may couple low voltage components and low voltage circuitry of the circuitry 315-b-1, among other components, with the voltage source 225-b-1. In some examples, the switches 305-b-1 and 310-b-1 may represent a single switching component with two switches. In some cases, the coupling may be in response to receiving one or more commands as described herein. Additionally, or alternatively, one or more voltages of the voltage source 220-b-1 and the voltage source 225-b-1 may be monitored, and a supply rail may be switched automatically as described herein. For example, the memory device 230-b-1 may monitor a voltage of the supply rail 240-b-1 and the voltage source 220-b-1 and/or the supply rail 245-b-1 and the voltage source 225-b-1 (e.g., a Vcc/Vccq detector).

In some cases, the memory device 230-b-1 may include a pad 320-b-1 (e.g., a pin, electrode, contact, other circuitry or conductive connection) for powering low voltage logic circuitry (e.g., sleep low voltage logic) and/or low volage components during a low power mode. In some cases, the pad 320-b-1 may be individual to the memory device 230-b-1, or shared among one or more memory devices 230. The pad 320-b-1 may be included in the switching component 305-b-1, or may be part of one or more memory devices 230. The pad 320-b-1 may be separate from one or more pads 320 used to power the datapath and I/O.

In the example of FIG. 3B, the circuit diagram 302 may include an alternate configuration involving reusing one or more pads for powering low voltage logic and/or low voltage components during the low power mode. For example, a same pad 320 used to power a datapath and I/O during active and sleep modes may power low voltage logic circuitry and/or low voltage components during a sleep mode. Additionally, or alternatively, with respect to FIGS. 3A and 3B, low voltage logic circuitry and/or components may be powered by a separate pin during active mode. For example, the low voltage logic and/or components may be powered by a pad 320-b-2 that may be included within the switching component 310-b-2 or within the one or more memory devices 230 that may be separate from a pad 320 (e.g., a pin) used for sensing, bias, high voltage operations or components. The memory system 210-b-2 may also include circuitry 315-b-2 and a switching component 305-b-1.

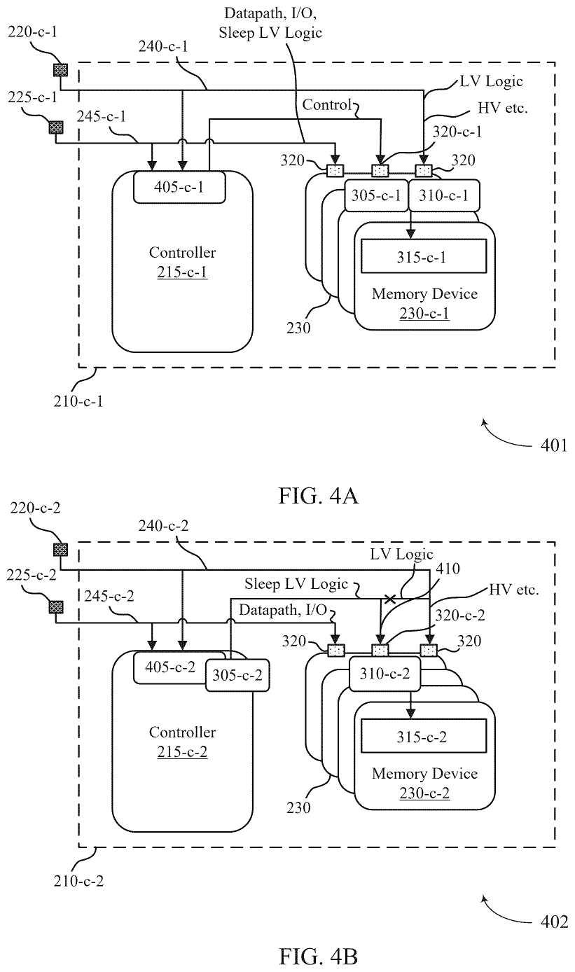

FIGS. 4A and 4B show examples of circuit diagrams 401 and 402 that support power supply for low power modes in memory in accordance with examples as disclosed herein. One or more aspects of the circuit diagrams 401 and 402 may implement or may be implemented by one or more aspects of the system 100 and the circuit diagrams 201, 202, 301, and 302. For example, the circuit diagrams 401 and 402 may illustrate circuitry of memory systems 210-c-1 and 210-c-2, including a controller 215-c-1 and a controller 215-c-2, respectively, and including one or more memory devices 230 such as a memory device 230-c-1 and a memory device 230-c-2. The memory system 210-c-1 may also include voltage sources 220-c-1 and 225-c-1 with supply rails 240-c-1 and 240-c-2, respectively, and the memory system 210-c-2 may include voltage sources 220-c-2 and 225-c-2 with supply rails 240-c-2 and 245-c-2, respectively, which may be examples of voltage sources 220 (e.g., Vcc) and 225 (e.g., Vccq) and supply rails 240 and 245 described with respect to FIGS. 2A-3B. The memory systems 210-c-1 and 210-c-2 may also include circuitry 315-c-1 and 315-c-2, respectively. In some cases, the circuit diagrams 401 and 402 may illustrate controller (e.g., ASIC) control of voltage source switching for low power modes.

For example, in the example of FIG. 4A, the controller 215-c-1 may include circuitry 405-c-1 coupled with the voltage rail 245-c-1, which may represent logic circuitry for determining whether to enter one or more memory devices 230 into a low power mode. For example, the circuitry 405-c-1 may include circuitry to monitor for one or more commands to enter a low power mode. Additionally, or alternatively, the circuitry 405-c-1 may be coupled with the voltage rail 240-c-1 and may include voltage monitoring circuitry to determine whether the voltage of the voltage source 220-c-1 (e.g., Vcc) and the supply rail 240-c-1 fails to satisfy a threshold voltage.

In some cases, the controller 215-c-1 may control switching voltage sources for a low power mode. For example, a switching component 305-c-1 for coupling one or more components with the voltage source 225-c-1 during a low power mode may be included on the one or more memory devices 230, and a switching component 310-c-1 for coupling the one or more components with the voltage source 220-c-1 during an active mode may also be included on the one or more memory devices 230. If the controller 215-c-1 determines to enter the one or more memory devices 230 into a low power mode (e.g., in response to a command, in response to monitoring one or more voltages), the controller 215-c-1 may transmit a control signal to a pad 320-c-1 (e.g., an electrode for receiving control signaling) coupled with the switch 305-c-1 and/or the switch 310-c-1 (e.g., coupled with a gate of a switch). In response to the control signal, the one or more memory devices 230 may couple the supply rail 245-c-1 with a supply node to power one or more components of the one or more memory devices 230 (e.g., low voltage components, SPB, one or more registers, SRAM) while decoupling the supply rail 220-c-1 from the supply node.

In some cases, transmitting the signal may be part of one or more operations to couple the one or more components of the one or more memory devices 230 with the voltage source 225-c-1 and with the supply rail 245-c-1. Further, the pad 320-c-1 may be a separate pad for control signaling, or may be a shared pad used for other control signaling for the switch components or other components. In some examples, the supply node of the one or more components may be coupled with a pad 320 supplying power from the supply rail 245-c-1. For example, low voltage logic circuitry and/or components of the one or more memory devices 230 may be powered by a same pad 320 as sensing, bias, and other high voltage operations during an active mode, and may be powered by a same pad 320 as a datapath and I/O circuitry during a low power mode in response to the coupling.

In the example of FIG. 4B, the circuit diagram 402 may include an alternate configuration involving inclusion of a switching component within a controller. For example, the controller 215-c-2 may include circuitry 405-c-2 that may be coupled with a switching component 305-c-2, where a switching component 310-c-2 may be on the one or more memory devices 230. In response to determining to enter the one or more memory devices 230 into a low power mode, the controller 215-c-2 may couple the supply rail 245-c-2 with one or more supply nodes associated with one or more components of the one or more memory devices 230. For example, a pad 320-c-2 may be used to power the one or more components, and may receive power from a rail 410 (e.g., a signal, an electrode or conductor) coupled with the voltage source 220-c-2 (via the rail 240-c-2), and with the switching component 305-c-2. During an active mode, the pad 320-c-2 may be coupled with the voltage source 220-c-2. In entering a low power mode, the switching component 305-c-2 may switch to couple the rail 410 with the voltage source 225-c-2 (via a coupling with the rail 245-c-2). In some cases, circuitry associated with supplying a voltage of the voltage supply 225-c-2 via the controller 215-c-2 may be on in case of power loss of the supply rail 240-c-2, and otherwise may be deactivated (e.g., decoupled). In some cases, the pad 320-c-2 may be a separate pad for powering low voltage logic and/or components of circuitry 215-c-2 during active modes, low power modes, or both, and may be separated from one or more pads 320 used for datapath and I/O and one or more pads 320 used for HV components.

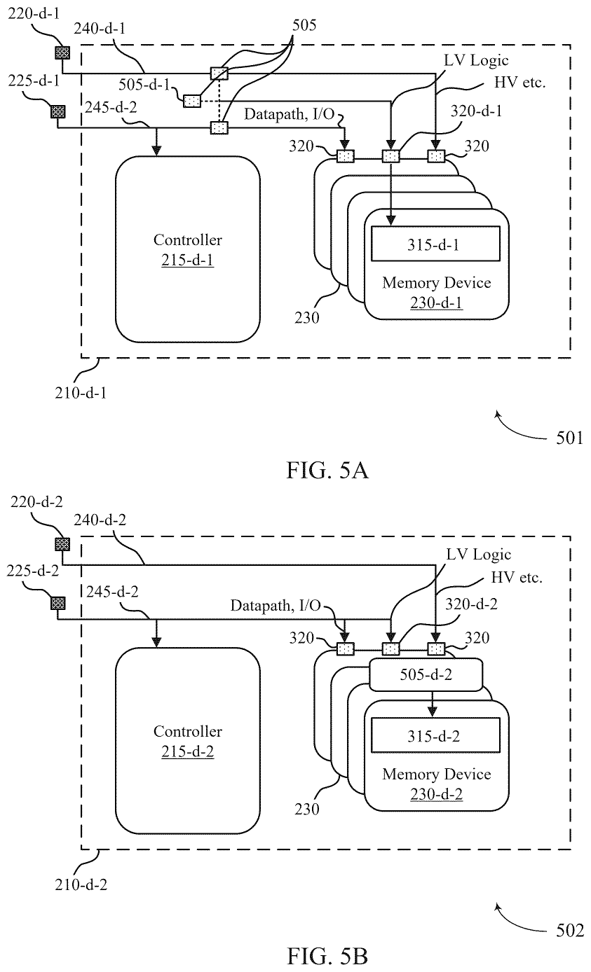

FIGS. 5A and 5B show examples of circuit diagrams 501 and 502 that support power supply for low power modes in memory in accordance with examples as disclosed herein. One or more aspects of the circuit diagrams 501 and 502 may implement or may be implemented by one or more aspects of the system 100 and the circuit diagrams 201, 202, 301, 302, 401, and 402. For example, the circuit diagrams 501 and 502 may illustrate circuitry of memory systems 210-d-1 and 210-d-2, each including a controller 215-d-1 and a controller 215-d-2, respectively, and including one or more memory devices 230 such as a memory device 230-d-1 and a memory device 230-d-2. The memory system 210-d-1 may also include voltage sources 220-c-1 and 225-c-1 with supply rails 240-d-1 and 240-d-2, respectively, and the memory system 210-d-2 may include voltage sources 220-d-2 and 225-d-2 with supply rails 240-d-2 and 245-d-2, respectively, which may be examples of voltage sources 220 (e.g., Vcc) and 225 (e.g., Vccq) and supply rails 240 and 245 described with respect to FIGS. 2A-4B. The memory systems 210-d-1 and 210-d-2 may also include circuitry 315-d-1 and 315-d-2, respectively. In some cases, the circuit diagrams 501 and 502 may illustrate additional methods for coupling alternative voltage sources.

In the example of FIG. 5A, the memory system 210-d-1 may include one or more physical connections 505. For example, during manufacturing, a pad 320-d-1 (or other pad 320) for supplying power to low voltage logic circuitry and/or components of the circuitry 315-d-1 may be physically coupled with the supply rail 240-d-1 (e.g., for Vcc), or with the supply rail 245-d-2 (e.g., for Vccq), in a package design for the memory system 210-d-1. For example, a printed circuit board (PCB) may include a physical coupling (e.g., a soldered/bonded wire) between the pad 320-d-1 and the supply rail 240-d-1, or between the pad 320-d-1 and the supply rail 245-d-2. Additionally, or alternatively, the memory system may be coupled with one or more other devices or other voltage sources via a connection 505-d-1. In some examples, a power management integrated circuit (PMIC) may be coupled with one or more memory devices 230 (e.g., PMIC of a same PCB, the PCB including the one or more memory devices 230), and may be used to couple different voltage sources as a part of power control operations. In the example of FIG. 5B, the memory system 210-d-2 may include a switching component 505-d-2, which may represent a physical metal switch that may be used to physically (e.g., by hand) switch a coupling of the pad 320-d-2 to be coupled with the supply rail 240-d-2 or coupled with the supply rail 245-d-2. Further, SRAM and registers, among other components, may support a variety of voltages during active or sleep modes as described herein.

In some examples, the techniques described herein with respect to FIG. 1-B may provide one or more advantages. For example, coupling one or more memory devices 230 with a voltage source associated with a lower voltage during a low power mode may reduce power up and ROM read cycling during exit wake up, as well as an overall cycling stress. Further, one or more trim settings (e.g., settings including timings, voltages for read, program, erase) or firmware may be preserved during a sleep mode, saving/reducing a next wake up time, while providing improved energy efficiency in sleep entry and exit. In some examples, using a lower voltage, such as Vccq, for one or more devices (e.g., SPB) may reduce leakage and thus retain data. In some examples, after sleep wake up, a controller interface, such as an ASIC Open NAND Flash Interface (ONFI), may be in low voltage swing terminated logic (LVSTL), while memory devices (e.g., NAND) may in some cases be reset to stub series terminated logic (SSTL). By implementing a backup voltage source, such as a Vccq back up ONFI set feature register, the memory devices may retain one or more ONFI configurations, and avoid ONFI re-training or re-write training configurations, further reducing boot-up time. Further, in automotive environments, if a relatively higher voltage, such as Vcc, experiences a power loss, primary data cache (PDC) or secondary data cache (SDC) data may be retained to enable recovery of data. Additionally, or alternatively, a controller, such as an ASIC, may store backup code in NAND PDC/SDC/RAM as a buffer during sleep to save ASIC leakage power on SRAM. Additionally, or alternatively, a switch voltage may be changed independently from Vcc external behavior and may be host controlled.

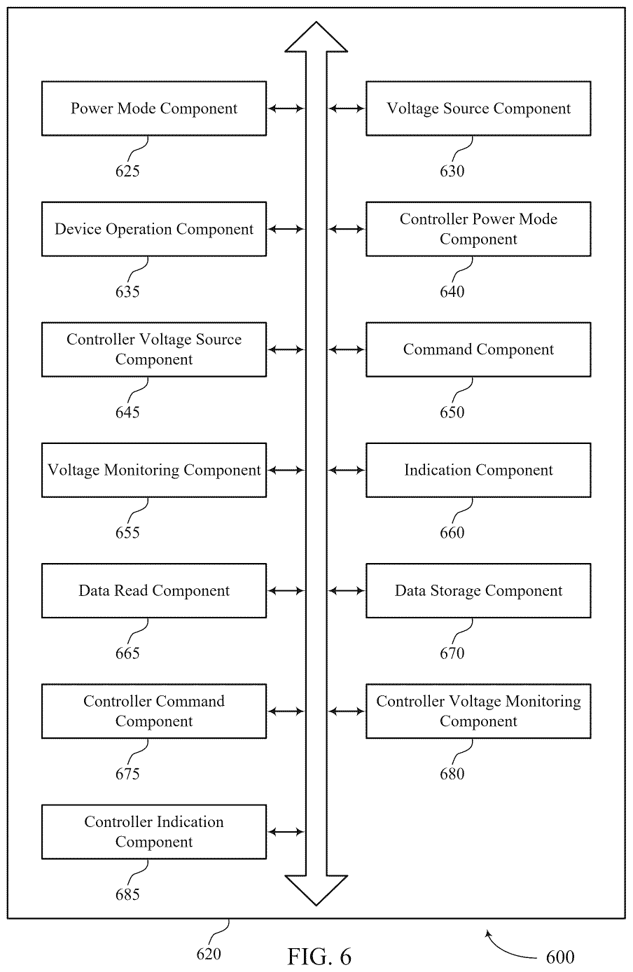

FIG. 6 shows a block diagram 600 of a memory system 620 that supports power supply for low power modes in memory in accordance with examples as disclosed herein. The memory system 620 may be an example of aspects of a memory system including a controller (e.g., including an ASIC) as described with reference to FIGS. 1 through 5. The memory system 620, or various components thereof, may be an example of means for performing various aspects of power supply for low power modes in memory as described herein. For example, the memory system 620 may include a power mode component 625, a voltage source component 630, a device operation component 635, a controller power mode component 640, a controller voltage source component 645, a command component 650, a voltage monitoring component 655, an indication component 660, a data read component 665, a data storage component 670, a controller command component 675, a controller voltage monitoring component 680, a controller indication component 685, or any combination thereof. Each of these components, or components of subcomponents thereof (e.g., one or more processors, one or more memories), may communicate, directly or indirectly, with one another (e.g., via one or more buses).

The power mode component 625 may be configured as or otherwise support a means for determining to enter a low power mode, the memory device including one or more components coupled with a first voltage source during an active mode, the first voltage source for powering the one or more components at a first voltage level. The voltage source component 630 may be configured as or otherwise support a means for coupling the one or more components of the memory device with a second voltage source in response to determining to enter the low power mode, the second voltage source for powering the one or more components of the memory device at a second voltage level.

In some examples, the command component 650 may be configured as or otherwise support a means for monitoring, during the active mode, a channel for one or more commands. In some examples, the command component 650 may be configured as or otherwise support a means for receiving a command to enter the low power mode, where determining to enter the low power mode is in response to receiving the command.

In some examples, the voltage monitoring component 655 may be configured as or otherwise support a means for monitoring, during the active mode, a voltage of the first voltage source of the memory device. In some examples, the voltage monitoring component 655 may be configured as or otherwise support a means for determining that the voltage of the first voltage source fails to satisfy a threshold voltage, where determining to enter the low power mode is in response to determining that the voltage of the first voltage source fails to satisfy the threshold voltage.

In some examples, to support coupling the one or more components of the memory device with the second voltage source, the voltage source component 630 may be configured as or otherwise support a means for decoupling, using a first switch (e.g., a switching component 310, a Vcc switch) on the memory device, a supply rail associated with the first voltage source with a power supply node associated with the one or more components. In some examples, to support coupling the one or more components of the memory device with the second voltage source, the voltage source component 630 may be configured as or otherwise support a means for coupling, using a second switch (e.g., a switching component 305, a Vccq switch) on the memory device, a supply rail associated with the second voltage source with the power supply node associated with the one or more components.

In some examples, the voltage source component 630 may be configured as or otherwise support a means for receiving, at the switch on the memory device from a device external to the memory device, a signal indicating to enter the low power mode, where coupling the supply rail associated with the second voltage source with the power supply node is in response to receiving the signal.

In some examples, the indication component 660 may be configured as or otherwise support a means for transmitting an indication that the one or more components are coupled with the second voltage source.

In some examples, the data read component 665 may be configured as or otherwise support a means for reading data stored in a ROM of a memory system including the memory device. In some examples, the data storage component 670 may be configured as or otherwise support a means for storing the data in volatile memory of the memory device, where the data is maintained in response to coupling the one or more components with the second voltage source during the low power mode.

In some examples, the second voltage level is lower than the first voltage level.

The device operation component 635 may be configured as or otherwise support a means for operating one or more memory devices of the memory system in an active mode, where, in the active mode, one or more components of the one or more memory devices are coupled with a first voltage source, the first voltage source providing a first voltage level. The controller power mode component 640 may be configured as or otherwise support a means for determining to enter the one or more memory devices into a low power mode. The controller voltage source component 645 may be configured as or otherwise support a means for performing one or more operations associated with coupling the one or more components of the one or more memory devices with a second voltage source of the memory system in response to determining to enter the one or more memory devices into the low power mode, the second voltage source providing a second voltage level that is different from the first voltage level.

In some examples, the controller command component 675 may be configured as or otherwise support a means for monitoring, during the active mode, a channel for one or more commands. In some examples, the controller command component 675 may be configured as or otherwise support a means for receiving a first command indicating to enter the low power mode, where determining to enter the one or more memory devices into the low power mode is in response to receiving the first command. In some examples, to perform the one or more operations, the controller command component 675 may be configured as or otherwise support a means for transmitting one or more second commands to the one or more memory devices indicating to enter the low power mode.

In some examples, the controller indication component 685 may be configured as or otherwise support a means for receiving one or more indications that the one or more components of the one or more memory devices are coupled with the second voltage source in response to transmitting the one or more second commands.

In some examples, the controller voltage monitoring component 680 may be configured as or otherwise support a means for monitoring, during the active mode, a voltage of the first voltage source of the memory system. In some examples, the controller voltage monitoring component 680 may be configured as or otherwise support a means for determining that the voltage of the first voltage source fails to satisfy a threshold voltage, where determining to enter the one or more memory devices into the low power mode is in response to determining that the voltage of the first voltage source fails to satisfy the threshold voltage.

In some examples, to support performing the one or more operations, the controller voltage source component 645 may be configured as or otherwise support a means for transmitting a signal to one or more switches on the one or more memory devices indicating to enter the low power mode.

In some examples, to support performing the one or more operations, the controller voltage source component 645 may be configured as or otherwise support a means for coupling, using one or more switches on the controller, one or more supply rails associated with the second voltage source with one or more power supply nodes associated with the one or more components of the one or more memory devices.

In some examples, the second voltage level is lower than the first voltage level.

In some examples, the described functionality of the memory system 620, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 620, or various components thereof, may be implemented at least in part by instructions (e.g., stored in memory, non-transitory computer-readable medium) executable by such at least one processor.

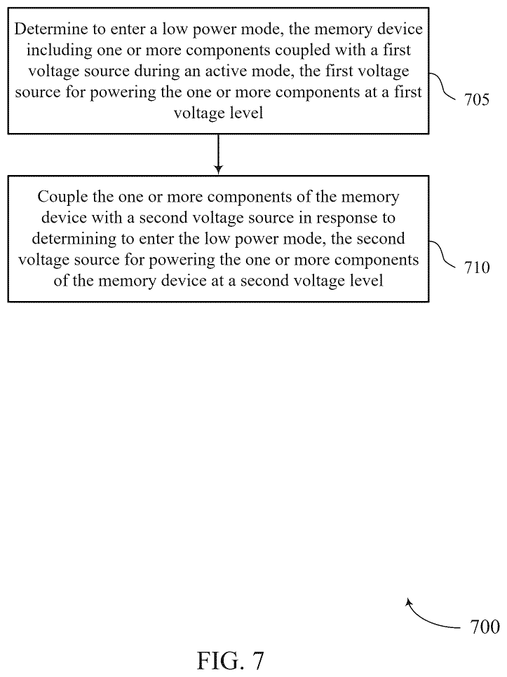

FIG. 7 shows a flowchart illustrating a method 700 that supports power supply for low power modes in memory in accordance with examples as disclosed herein. The operations of method 700 may be implemented by a memory system or its components as described herein. For example, the operations of method 700 may be performed by a memory system as described with reference to FIGS. 1 through 6. In some examples, a memory system may execute a set of instructions to control the functional elements of the device to perform the described functions. Additionally, or alternatively, the memory system may perform aspects of the described functions using special-purpose hardware.

At 705, the method may include determining to enter a low power mode, the memory device including one or more components coupled with a first voltage source during an active mode, the first voltage source for powering the one or more components at a first voltage level. In some examples, aspects of the operations of 705 may be performed by a power mode component 625 as described with reference to FIG. 6.

At 710, the method may include coupling the one or more components of the memory device with a second voltage source in response to determining to enter the low power mode, the second voltage source for powering the one or more components of the memory device at a second voltage level. In some examples, aspects of the operations of 710 may be performed by a voltage source component 630 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for determining to enter a low power mode, the memory device including one or more components coupled with a first voltage source during an active mode, the first voltage source for powering the one or more components at a first voltage level and coupling the one or more components of the memory device with a second voltage source in response to determining to enter the low power mode, the second voltage source for powering the one or more components of the memory device at a second voltage level.

Aspect 2: The method, apparatus, or non-transitory computer-readable medium of aspect 1, further including operations, features, circuitry, logic, means, or instructions, or any combination thereof for monitoring, during the active mode, a channel for one or more commands and receiving a command to enter the low power mode, where determining to enter the low power mode is in response to receiving the command.

Aspect 3: The method, apparatus, or non-transitory computer-readable medium of any of aspects 1 through 2, further including operations, features, circuitry, logic, means, or instructions, or any combination thereof for monitoring, during the active mode, a voltage of the first voltage source of the memory device and determining that the voltage of the first voltage source fails to satisfy a threshold voltage, where determining to enter the low power mode is in response to determining that the voltage of the first voltage source fails to satisfy the threshold voltage.

Aspect 4: The method, apparatus, or non-transitory computer-readable medium of any of aspects 1 through 3, where coupling the one or more components of the memory device with the second voltage source includes operations, features, circuitry, logic, means, or instructions, or any combination thereof for decoupling, using a first switch (e.g., a switching component 310, a Vcc switch) on the memory device, a supply rail associated with the first voltage source with a power supply node associated with the one or more components and coupling, using a second switch (e.g., using a switching component 305, a Vccq switch) on the memory device, a supply rail associated with the second voltage source with the power supply node associated with the one or more components.

Aspect 5: The method, apparatus, or non-transitory computer-readable medium of aspect 4, further including operations, features, circuitry, logic, means, or instructions, or any combination thereof for receiving, at the switch (e.g., a switch including one or more of a switching component 305 and/or 310) on the memory device from a device external to the memory device, a signal indicating to enter the low power mode, where coupling the supply rail associated with the second voltage source with the power supply node is in response to receiving the signal.

Aspect 6: The method, apparatus, or non-transitory computer-readable medium of any of aspects 1 through 5, further including operations, features, circuitry, logic, means, or instructions, or any combination thereof for transmitting an indication that the one or more components are coupled with the second voltage source.

Aspect 7: The method, apparatus, or non-transitory computer-readable medium of any of aspects 1 through 6, further including operations, features, circuitry, logic, means, or instructions, or any combination thereof for reading data stored in a ROM of a memory system including the memory device and storing the data in volatile memory of the memory device, where the data is maintained in response to coupling the one or more components with the second voltage source during the low power mode.

Aspect 8: The method, apparatus, or non-transitory computer-readable medium of any of aspects 1 through 7, where the second voltage level is lower than the first voltage level.

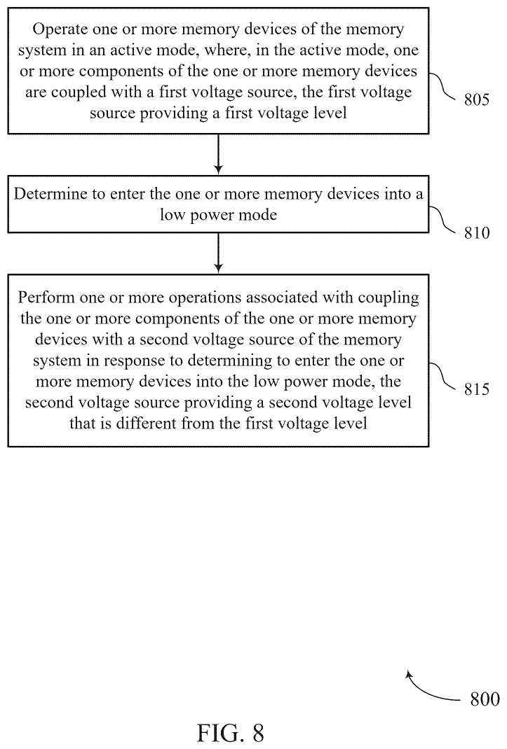

FIG. 8 shows a flowchart illustrating a method 800 that supports power supply for low power modes in memory in accordance with examples as disclosed herein. The operations of method 800 may be implemented by a memory system or its components as described herein (e.g., by a controller of the memory system, by an ASIC of the memory system). For example, the operations of method 800 may be performed by a memory system as described with reference to FIGS. 1 through 6. In some examples, a memory system may execute a set of instructions to control the functional elements of the device to perform the described functions. Additionally, or alternatively, the memory system may perform aspects of the described functions using special-purpose hardware.

At 805, the method may include operating one or more memory devices of the memory system in an active mode, where, in the active mode, one or more components of the one or more memory devices are coupled with a first voltage source, the first voltage source providing a first voltage level. In some examples, aspects of the operations of 805 may be performed by a device operation component 635 as described with reference to FIG. 6.

At 810, the method may include determining to enter the one or more memory devices into a low power mode. In some examples, aspects of the operations of 810 may be performed by a controller power mode component 640 as described with reference to FIG. 6.

At 815, the method may include performing one or more operations associated with coupling the one or more components of the one or more memory devices with a second voltage source of the memory system in response to determining to enter the one or more memory devices into the low power mode, the second voltage source providing a second voltage level that is different from the first voltage level. In some examples, aspects of the operations of 815 may be performed by a controller voltage source component 645 as described with reference to FIG. 6.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 9: A method, apparatus, or non-transitory computer-readable medium including operations, features, circuitry, logic, means, or instructions, or any combination thereof for operating one or more memory devices of the memory system in an active mode, where, in the active mode, one or more components of the one or more memory devices are coupled with a first voltage source, the first voltage source providing a first voltage level; determining to enter the one or more memory devices into a low power mode; and performing one or more operations associated with coupling the one or more components of the one or more memory devices with a second voltage source of the memory system in response to determining to enter the one or more memory devices into the low power mode, the second voltage source providing a second voltage level that is different from the first voltage level.

Aspect 10: The method, apparatus, or non-transitory computer-readable medium of aspect 9, further including operations, features, circuitry, logic, means, or instructions, or any combination thereof for monitoring, during the active mode, a channel for one or more commands and receiving a first command indicating to enter the low power mode, where determining to enter the one or more memory devices into the low power mode is in response to receiving the first command, and where performing the one or more operations includes transmitting one or more second commands to the one or more memory devices indicating to enter the low power mode.

Aspect 11: The method, apparatus, or non-transitory computer-readable medium of aspect 10, further including operations, features, circuitry, logic, means, or instructions, or any combination thereof for receiving one or more indications that the one or more components of the one or more memory devices are coupled with the second voltage source in response to transmitting the one or more second commands.

Aspect 12: The method, apparatus, or non-transitory computer-readable medium of any of aspects 9 through 11, further including operations, features, circuitry, logic, means, or instructions, or any combination thereof for monitoring, during the active mode, a voltage of the first voltage source of the memory system and determining that the voltage of the first voltage source fails to satisfy a threshold voltage, where determining to enter the one or more memory devices into the low power mode is in response to determining that the voltage of the first voltage source fails to satisfy the threshold voltage.

Aspect 13: The method, apparatus, or non-transitory computer-readable medium of aspect 12, where performing the one or more operations includes operations, features, circuitry, logic, means, or instructions, or any combination thereof for transmitting a signal to one or more switches on the one or more memory devices indicating to enter the low power mode.

Aspect 14: The method, apparatus, or non-transitory computer-readable medium of any of aspects 12 through 13, where performing the one or more operations includes operations, features, circuitry, logic, means, or instructions, or any combination thereof for coupling, using one or more switches on the controller, one or more supply rails associated with the second voltage source with one or more power supply nodes associated with the one or more components of the one or more memory devices.

Aspect 15: The method, apparatus, or non-transitory computer-readable medium of any of aspects 9 through 14, where the second voltage level is lower than the first voltage level.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 16: A system, including: one or more memory devices including one or more memory arrays; a controller coupled with the one or more memory devices; a first voltage source coupled with the one or more memory devices, the first voltage source configured to power one or more components of the one or more memory devices at a first voltage level; and a second voltage source coupled with the one or more memory devices, the second voltage source configured to power the one or more components of the one or more memory devices at a second voltage level, the system being configured to couple the one or more memory devices with the first voltage source during an active mode and to couple the one or more memory devices with the second voltage source during a low power mode.

Aspect 17: The system of aspect 16, further including: one or more first switching components (e.g., a switching component 310, a Vcc switch) located on the one or more memory devices, where the one or more first switching components are configured to couple one or more supply rails associated with the first voltage source with one or more power supply nodes associated with the one or more memory devices.

Aspect 18: The system of any of aspects 16 through 17, further including: one or more second switching components (e.g., a switching component 305, a Vccq switch) coupled with the one or more memory devices, where the one or more second switching components are configured to couple one or more supply rails associated with the second voltage source with one or more power supply nodes associated with the one or more memory devices.

Aspect 19: The system of aspect 18, where the one or more second switching components are located on the one or more memory devices.

Aspect 20: The system of any of aspects 18 through 19, where the one or more second switching components are located on the controller.

Aspect 21: The system of any of aspects 16 through 20, further including: voltage monitoring circuitry coupled with the first voltage source and configured to monitor a voltage of the first voltage source, where the voltage monitoring circuitry is configured to output, to one or more switching components in response to determining that the voltage of the first voltage source fails to satisfy a threshold, a signal indicating to couple the one or more components of the one or more memory devices with the second voltage source.

Aspect 22: The system of aspect 21, where the voltage monitoring circuitry is located on the controller.

Aspect 23: The system of any of aspects 21 through 22, where the voltage monitoring circuitry is located on the one or more memory devices.

Aspect 24: The system of any of aspects 21 through 23, where the second voltage level is lower than the first voltage level.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
one or more memory arrays; and
processing circuitry coupled with the one or more memory arrays and configured to cause the memory device to:
determine to enter a low power mode, the memory device comprising one or more components coupled with a first voltage source during an active mode, the first voltage source for powering the one or more components at a first voltage level; and
couple the one or more components of the memory device with a second voltage source in response to determining to enter the low power mode, the second voltage source for powering the one or more components of the memory device at a second voltage level.

2. The memory device of claim 1, wherein the processing circuitry is further configured to cause the memory device to:
monitor, during the active mode, a channel for one or more commands; and
receive a command to enter the low power mode, wherein determining to enter the low power mode is in response to receiving the command.

3. The memory device of claim 1, wherein the processing circuitry is further configured to cause the memory device to:
monitor, during the active mode, a voltage of the first voltage source of the memory device; and
determine that the voltage of the first voltage source fails to satisfy a threshold voltage, wherein determining to enter the low power mode is in response to determining that the voltage of the first voltage source fails to satisfy the threshold voltage.

4. The memory device of claim 1, wherein coupling the one or more components of the memory device with the second voltage source comprises the processing circuitry configured to cause the memory device to:
decouple, using a first switch on the memory device, a supply rail associated with the first voltage source with a power supply node associated with the one or more components; and
couple, using a second switch on the memory device, a supply rail associated with the second voltage source with the power supply node associated with the one or more components.

5. The memory device of claim 4, wherein the processing circuitry is further configured to cause the memory device to:
receive, at the second switch on the memory device from a device external to the memory device, a signal indicating to enter the low power mode, wherein coupling the supply rail associated with the second voltage source with the power supply node is in response to receiving the signal.

6. The memory device of claim 1, wherein the processing circuitry is further configured to cause the memory device to:
transmit an indication that the one or more components are coupled with the second voltage source.

7. The memory device of claim 1, wherein the processing circuitry is further configured to cause the memory device to:
read data stored in a read-only memory of a memory system comprising the memory device; and
store the data in volatile memory of the memory device, wherein the data is maintained in response to coupling the one or more components with the second voltage source during the low power mode.

8. The memory device of claim 1, wherein the second voltage level is lower than the first voltage level.

9. A memory system, comprising:
one or more memory devices; and
a controller coupled with the one or more memory devices and configured to cause the memory system to:
operate the one or more memory devices of the memory system in an active mode, wherein, in the active mode, one or more components of the one or more memory devices are coupled with a first voltage source, the first voltage source providing a first voltage level;
determine to enter the one or more memory devices into a low power mode; and
perform one or more operations associated with coupling the one or more components of the one or more memory devices with a second voltage source of the memory system in response to determining to enter the one or more memory devices into the low power mode, the second voltage source providing a second voltage level that is different from the first voltage level.

10. The memory system of claim 9, wherein the controller is further configured to cause the memory system to:
monitor, during the active mode, a channel for one or more commands; and
receive a first command indicating to enter the low power mode, wherein determining to enter the one or more memory devices into the low power mode is in response to receiving the first command, and wherein perform the one or more operations comprises the controller configured to cause the memory system to:
transmit one or more second commands to the one or more memory devices indicating to enter the low power mode.

11. The memory system of claim 10, wherein the controller is further configured to cause the memory system to:
receive one or more indications that the one or more components of the one or more memory devices are coupled with the second voltage source in response to transmitting the one or more second commands.

12. The memory system of claim 9, wherein the controller is further configured to cause the memory system to:
monitor, during the active mode, a voltage of the first voltage source of the memory system; and
determine that the voltage of the first voltage source fails to satisfy a threshold voltage, wherein determining to enter the one or more memory devices into the low power mode is in response to determining that the voltage of the first voltage source fails to satisfy the threshold voltage.

13. The memory system of claim 12, wherein performing the one or more operations comprises the controller configured to cause the memory system to:
transmit a signal to one or more switches on the one or more memory devices indicating to enter the low power mode.

14. The memory system of claim 12, wherein performing the one or more operations comprises the controller configured to cause the memory system to:
couple, using one or more switches on the controller, one or more supply rails associated with the second voltage source with one or more power supply nodes associated with the one or more components of the one or more memory devices.

15. The memory system of claim 9, wherein the second voltage level is lower than the first voltage level.

16. A system, comprising:
one or more memory devices comprising one or more memory arrays;
a controller coupled with the one or more memory devices;
a first voltage source coupled with the one or more memory devices, the first voltage source configured to power one or more components of the one or more memory devices at a first voltage level; and
a second voltage source coupled with the one or more memory devices, the second voltage source configured to power the one or more components of the one or more memory devices at a second voltage level, the system being configured to couple the one or more memory devices with the first voltage source during an active mode and to couple the one or more memory devices with the second voltage source during a low power mode.

17. The system of claim 16, further comprising:
one or more first switching components located on the one or more memory devices, wherein the one or more first switching components are configured to couple one or more supply rails associated with the first voltage source with one or more power supply nodes associated with the one or more memory devices.

18. The system of claim 16, further comprising:
one or more second switching components coupled with the one or more memory devices, wherein the one or more second switching components are configured to couple one or more supply rails associated with the second voltage source with one or more power supply nodes associated with the one or more memory devices.

19. The system of claim 18, wherein the one or more second switching components are located on the one or more memory devices.

20. The system of claim 18, wherein the one or more second switching components are located on the controller.

21. The system of claim 16, further comprising:
voltage monitoring circuitry coupled with the first voltage source and configured to monitor a voltage of the first voltage source, wherein the voltage monitoring circuitry is configured to output, to one or more switching components in response to determining that the voltage of the first voltage source fails to satisfy a threshold, a signal indicating to couple the one or more components of the one or more memory devices with the second voltage source.

22. The system of claim 21, wherein the voltage monitoring circuitry is located on the controller.

23. The system of claim 21, wherein the voltage monitoring circuitry is located on the one or more memory devices.

24. The system of claim 21, wherein the second voltage level is lower than the first voltage level.
